(19) United States
(12) Patent Application Publication
(10) Pub. No.: US 2025/0337255 A1
(43) Pub. Date: Oct. 30, 2025

(54) BATTERY MANAGEMENT APPARATUS AND CELL BALANCING METHOD THEREOF

(71) Applicants: HYUNDAI MOTOR COMPANY, Seoul (KR); KIA CORPORATION, Seoul (KR)

(72) Inventor: Yo Han Baek, Hwaseong-si (KR)

(73) Assignees: HYUNDAI MOTOR COMPANY, Seoul (KR); KIA CORPORATION, Seoul (KR)

(21) Appl. No.: 18/920,587

(22) Filed: Oct. 18, 2024

(30) Foreign Application Priority Data
Apr. 29, 2024 (KR) 10-2024-0056971

(51) Int. Cl. H02J 7/00; H01M 10/42; H01M 10/44

(52) U.S. Cl. CPC H02J 7/0016; H01M 10/425; H01M 10/441; H02J 7/0047; H02J 7/00712; H01M 2010/4271

(57) ABSTRACT

A battery management apparatus for perform cell balancing of a battery and a cell balancing method thereof are provided. The battery management apparatus includes a detection circuit that detects pieces of state information of battery cells, a cell balancing circuit that controls whether to discharge each of the battery cells, and a control unit connected to the detection circuit and the cell balancing circuit. The control unit determines whether there is a need to perform cell balancing based on the pieces of state information of the battery cells; groups the battery cells into at least two groups, when it is determined that there is the need to perform the cell balancing; determines whether to apply a group control strategy based on the pieces of state information of the battery cells; and simultaneously controls balancing switches in the cell balancing circuit to perform the cell balancing.

### CROSS-REFERENCE TO RELATED APPLICATION

This application claims the benefit of and priority to Korean Patent Application No. 10-2024-0056971, filed in the Korean Intellectual Property Office on Apr. 29, 2024, the entire contents of which are incorporated herein by reference.

### TECHNICAL FIELD

The present disclosure relates to a battery management apparatus for performing cell balancing of a battery and a cell balancing method thereof.

### BACKGROUND

As a voltage deviation between individual battery cells is small, a high voltage battery pack system may show maximum performance. However, because a high voltage battery pack is exposed to various environment conditions and repeats charging and discharging, a cell voltage deviation increases. To prevent deterioration in performance due to such a cell voltage deviation, a battery management system (BMS) performs cell balancing such as the cell voltage deviation decreases using cell balancing hardware and software. There are an active balancing scheme and a passive balancing scheme in a cell balancing scheme. The passive balancing scheme is usually used to rationalize costs in industry. The passive balancing scheme is a resistance discharge scheme. Because such a passive balancing scheme fixes a size of a cell balancing resistor based on a state in which the cell voltage is maximum, there is a problem in which the cell balancing speed is slow because the cell balancing current is small in magnitude when the cell voltage decreases.

To address such a problem, because a plurality of balancing switches is simultaneously turned on to shorten a time taken to alternately turn on an odd balancing switch and an even balancing switch, the cell balancing speed may be improved. However, when the plurality of balancing switches is simultaneously turned on, because a short path is formed and a large current flows in the balancing switch and resistors, there is a risk that the balancing switch and the resistors may be damaged. The subject matter described in this background section is intended to promote an understanding of the background of the disclosure and thus may include subject matter that is not already known to those of ordinary skill in the art.

### SUMMARY

The present disclosure has been made to solve the above-mentioned problems occurring in the prior art while advantages achieved by the prior art are maintained intact.

An aspect of the present disclosure provides a battery management apparatus for controlling a cell balancing switch to increase the magnitude of a cell balancing current when a cell voltage decreases to address a problem in which a cell balancing speed is slow as the cell voltage decreases. The present disclosure also provides a cell balancing method thereof.

Another aspect of the present disclosure provides a battery management apparatus for grouping a plurality of cells adjacent to each other among cell balancing target cells and simultaneously turning on a plurality of balancing switches corresponding to the plurality of the grouped cells to form a short path between the switches to selectively use a cell balancing resistor. The present disclosure also provides a cell balancing method thereof.

The technical problems to be solved by the present disclosure are not limited to the aforementioned problems. Any other technical problems not mentioned herein should be clearly understood from the following description by those having ordinary skill in the art to which the present disclosure pertains.

According to an aspect of the present disclosure, a battery management apparatus may include a detection circuit that detects pieces of state information of battery cells, a cell balancing circuit that controls whether to discharge each of the battery cells, and a control unit connected to the detection circuit and the cell balancing circuit. The control unit may determine whether there is a need to perform cell balancing based on the pieces of state information of the battery cells. The control unit may group the battery cells into at least two groups, when it is determined that there is the need to perform the cell balancing. The control unit may determine whether to apply a group control strategy based on the pieces of state information of the battery cells. The control unit may simultaneously control balancing switches in the cell balancing circuit, the balancing switches being mapped to the grouped battery cells, to perform the cell balancing, when it is determined to apply the group control strategy.

The control unit may group at least two battery cells adjacent to each other among the battery cells.

The control unit may determine whether there is a need to perform balancing for each battery cell based on a balancing required time for each battery cell. The control unit may generate a first group based on a result of determining whether there is the need to perform the balancing for each battery cell and a first group filter. The control unit may generate a second group based on a result of determining whether there is the need to perform the balancing for each battery cell and a second group filter.

The control unit may determine whether cell balancing of battery cells of a first group among the at least two groups is performed in a previous period. The control unit may determine cell balancing of battery cells of a second group among the at least two groups, when it is determined that the cell balancing of the battery cells of the first group is performed. The control unit may turn on second group balancing switches mapped to the battery cells of the second group. The control unit may determine whether a predetermined time elapses after turning on the second group balancing switches. The control unit may turn off the second group balancing switches, when it is determined that the predetermined time elapses.

The control unit may determine whether cell balancing of battery cells of a first group among the at least two groups is performed in a previous period. The control unit may determine the cell balancing of the battery cells of the first group, when it is determined that the cell balancing of the battery cells of the first group is not performed. The control unit may turn on first group balancing switches mapped to the battery cells of the first group. The control unit may determine whether a predetermined time elapses after turning on the first group balancing switches. The control unit may turn off the first group balancing switches, when it is determined that the predetermined time elapses.

The control unit may determine whether a maximum cell voltage is less than a predetermined trigger voltage and may determine to apply the group control strategy, when it is determined that the maximum cell voltage is less than the predetermined trigger voltage.

The predetermined trigger voltage may be previously selected with regard to ratings of elements constituting a system.

The control unit may determine whether to end cell balancing of the grouped battery cells based on a balancing required time of the battery cells.

The control unit may determine whether to end cell balancing of the grouped battery cells based on whether a voltage of the battery cells reaches a predetermined target voltage.

The control unit may determine whether to end cell balancing of the grouped battery cells based on whether a state of charge (SOC) of the battery cells reaches a predetermined target SOC.

According to another aspect of the present disclosure, a cell balancing method of a battery management apparatus may include determining whether there is a need to perform cell balancing based on pieces of state information of battery cells, the pieces of state information being detected by a detection circuit. The cell balancing method may include grouping the battery cells into at least two groups, when it is determined that there is the need to perform the cell balancing. The cell balancing method may include determining whether to apply a group control strategy based on the pieces of state information of the battery cells. The cell balancing method may include simultaneously controlling balancing switches in a cell balancing circuit, the balancing switches being mapped to the grouped battery cells, to perform the cell balancing, when it is determined to apply the group control strategy.

Grouping the battery cells into at least two groups may include grouping at least two battery cells adjacent to each other among the battery cells.

Grouping the battery cells into at least two groups may include determining whether there is a need to perform balancing for each battery cell based on a balancing required time for each battery cell. Grouping the battery cells into at least two groups may include generating a first group based on a result of determining whether there is the need to perform the balancing for each battery cell and a first group filter. Grouping the battery cells into at least two groups may include generating a second group based on a result of determining whether there is the need to perform the balancing for each battery cell and a second group filter.

Performing the cell balancing may include determining whether cell balancing of battery cells of a first group among the at least two groups is performed in a previous period. Performing the cell balancing may include determining cell balancing of battery cells of a second group among the at least two groups, when it is determined that the cell balancing of the battery cells of the first group is performed. Performing the cell balancing may include turning on second group balancing switches mapped to the battery cells of the second group. Performing the cell balancing may include determining a predetermined time elapses after turning on the second group balancing switches. Performing the cell balancing may include turning off the second group balancing switches, when it is determined that the predetermined time elapses.

Performing the cell balancing may include determining whether cell balancing of battery cells of a first group among the at least two groups is performed in a previous period. Performing the cell balancing may include determining the cell balancing of the battery cells of the first group, when it is determined that the cell balancing of the battery cells of the first group is not performed. Performing the cell balancing may include turning on first group balancing switches mapped to the battery cells of the first group. Performing the cell balancing may include determining a predetermined time elapses after turning on the first group balancing switches. Performing the cell balancing may include turning off the first group balancing switches, when it is determined that the predetermined time elapses.

Determining whether to apply the group control strategy may include determining whether a maximum cell voltage is less than a predetermined trigger voltage. Determining whether to apply the group control strategy may include determining to apply the group control strategy, when it is determined that the maximum cell voltage is less than the predetermined trigger voltage.

The battery management method may further include determining whether to end cell balancing of the grouped battery cells based on a balancing required time of the battery cells.

The battery management method may further include determining whether to end cell balancing of the grouped battery cells based on whether a voltage of the battery cells reaches a predetermined target voltage.

The battery management method may further include determining whether to end cell balancing of the grouped battery cells based on whether an SOC of the battery cells reaches a predetermined target SOC.

### BRIEF DESCRIPTION OF THE DRAWINGS

The above and other objects, features, and advantages of the present disclosure should be more apparent from the following detailed description taken in conjunction with the accompanying drawings:

FIG. 1 is a block diagram illustrating a battery system according to an embodiment of the present disclosure;

FIG. 2 is a block diagram illustrating a battery system according to another embodiment of the present disclosure;

FIG. 3 is a block diagram illustrating a configuration of a battery management apparatus according to an embodiment of the present disclosure;

FIG. 4 is a circuit diagram illustrating a cell balancing circuit according to an embodiment of the present disclosure;

FIGS. 5A, 5B, 5C, and 5D are drawings for describing selection of a trigger voltage according to an embodiment of the present disclosure;

FIGS. 6A and 6B are flowcharts illustrating a cell balancing method of a battery management apparatus according to an embodiment of the present disclosure;

FIG. 7 is a flowchart illustrating a battery cell grouping process according to an embodiment of the present disclosure;

FIG. 8 is a drawing for describing a method for determining whether there is a need to perform balancing for each battery cell according to an embodiment of the present disclosure;

FIGS. 9A and 9B are drawings for describing cell grouping according to an embodiment of the present disclosure;

FIGS. 10A and 10B are drawings for describing group control according to an embodiment of the present disclosure;

FIGS. 11A and 11B are drawings for describing a cell balancing circuit according to another embodiment of the present disclosure;

FIGS. 12A, 12B, 12C, and 12D illustrate performance comparison graphs according to a ratio of balancing resistors according to another embodiment of the present disclosure;

FIGS. 13A and 13B are drawings for describing cell balancing switch control according to another embodiment of the present disclosure; and

FIG. 14 is a block diagram illustrating a computing system associated with a battery management apparatus and a cell balancing method thereof according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical or equivalent components are designated by the identical numerals even when the components are displayed on other drawings. In addition, a detailed description of well-known features or functions has been omitted in order not to unnecessarily obscure the gist of the present disclosure.

In describing components of embodiments of the present disclosure, the terms first, second, A, B, (a), (b), and the like may be used herein. These terms are only used to distinguish one component from another component and do not limit the corresponding components irrespective of the order or priority of the corresponding components. Furthermore, unless otherwise defined, all terms including technical and scientific terms used herein have the same meanings as being generally understood by those having ordinary skill in the art to which the present disclosure pertains. Such terms as those defined in a generally used dictionary should be interpreted as having meanings equal to the contextual meanings in the relevant field of art. The terms should not be interpreted as having ideal or excessively formal meanings unless clearly defined as having such in the present disclosure. When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

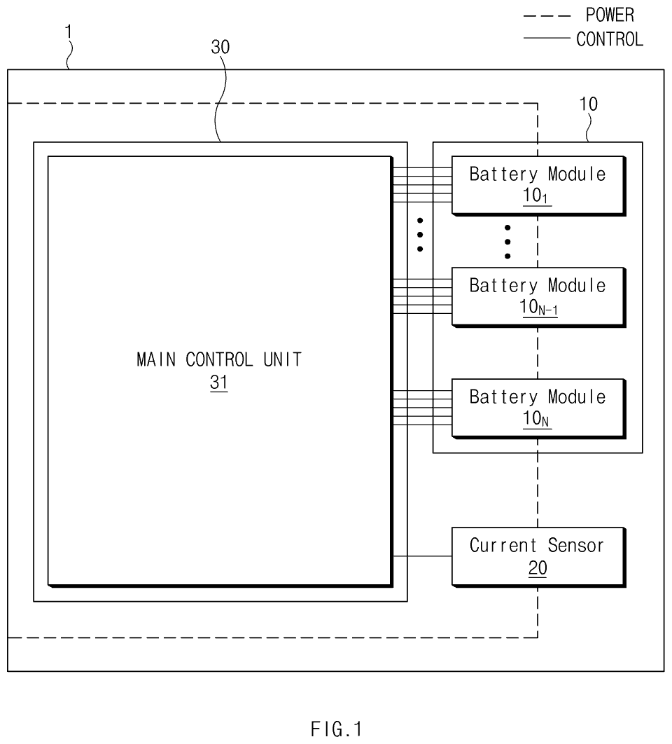

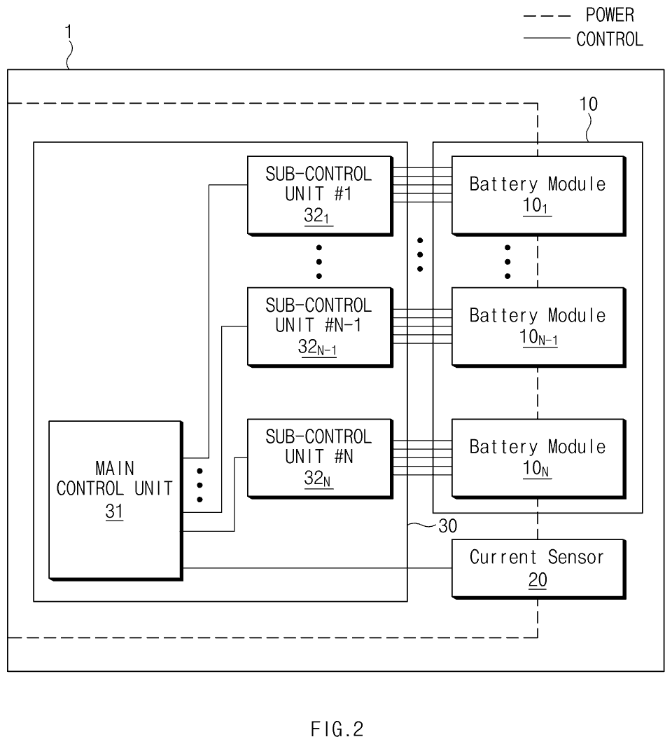

FIG. 1 is a block diagram illustrating a battery system according to an embodiment of the present disclosure. FIG. 2 is a block diagram illustrating a battery system according to another embodiment of the present disclosure.

Referring to FIGS. 1 and 2, a battery system 1 may include a battery pack 10, a current sensor 20, and a battery management apparatus 30.

The battery pack 10 may be a high voltage battery for supplying power necessary to drive a drive motor of a vehicle. The drive motor may convert power supplied from the battery pack 10 into electric power and may deliver the electric power to vehicle wheels.

The battery pack 10 may comprise a plurality of battery modules 10₁, . . . , 10_{N-1}, and 10_{N}. Each battery module 10₁, . . . , 10_{N-1}, or 10_{N} may comprise a plurality of battery cells.

The current sensor 20 may measure a current of the battery pack 10. The current sensor 20 may transmit the measured current value to the battery management apparatus 30.

The battery management apparatus 30 may serve to optimally manage the battery pack 10 to increase energy efficiency of the battery pack 10 and extend the life of the battery pack 10. The battery management apparatus 30 may monitor a voltage, a current, a temperature, and the like of the battery pack 10 in real time to prevent the battery pack 10 from being overcharged or overdischarged. The battery management apparatus 30 may calculate a remaining capacity, i.e., a state of charge (SOC) of the battery pack 10. Furthermore, the battery management apparatus 30 may predict life, i.e., a state of health (SOH) of the battery pack 10. The battery management apparatus 30 may perform cell balancing (or balancing) for correcting a characteristic difference due to a deviation between battery cells.

The battery management apparatus 30 may include only a main control unit 31 as shown in FIG. 1 or may include a main control unit 31 and a plurality of sub-control units 32₁, 32_{N-1}, and 32_{N} as shown in FIG. 2. The main control unit 31 may be a battery management unit (BMU), which may collect information, such as a voltage, a current, and/or a temperature of the battery pack 10. The main control unit 31 may control the battery system 1 in an overall manner based on the collected information. Each sub-control unit 32₁, 32_{N-1}, or 32_{N} may be a cell monitoring unit (CMU), which may be directly connected to a plurality of battery cells constituting each battery module 10₁, . . . , 10_{N-1}, or 10_{N}. Each sub-control unit 32₁, 32_{N-1}, or 32_{N} may measure a voltage, a current, and/or the like of each battery cell to monitor the measured value. Each sub-control unit 32₁, 32_{N-1}, or 32_{N} may transmit the measured value to the main control unit 31.

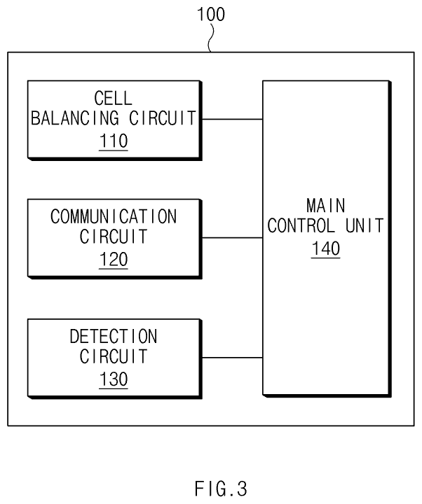

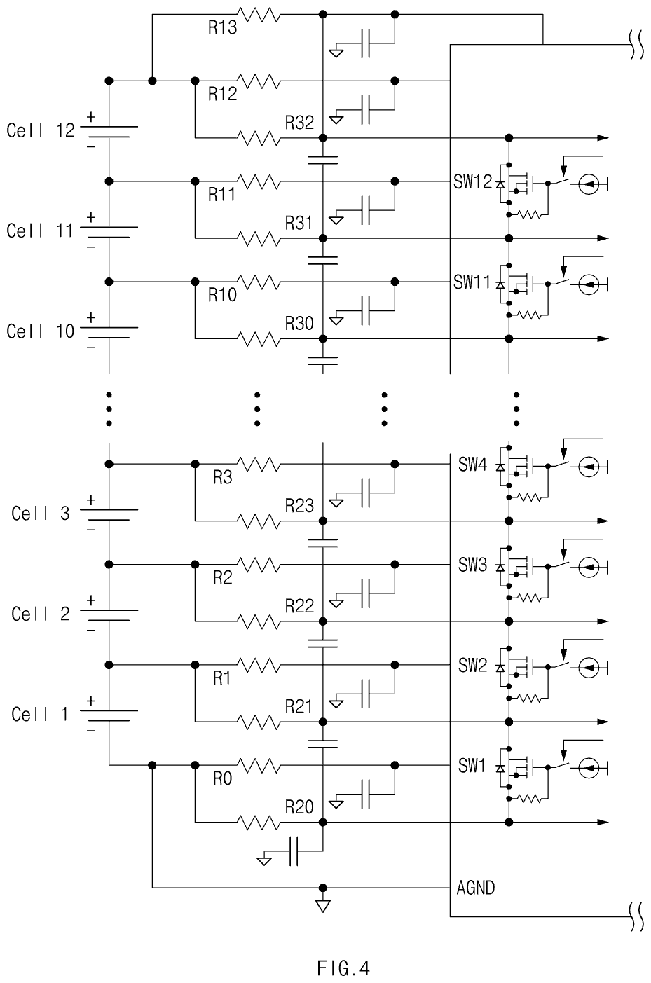

FIG. 3 is a block diagram illustrating a configuration of a battery management apparatus according to an embodiment of the present disclosure. FIG. 4 is a circuit diagram illustrating a cell balancing circuit according to an embodiment of the present disclosure.

A battery management apparatus 100 may correspond to a battery management apparatus 30 shown in FIG. 1 or FIG. 2. Such a battery management apparatus 100 may include a cell balancing circuit 110, a communication circuit 120, a detection circuit 130, and a control unit 140.

The cell balancing circuit 110 may be included in a main control unit 31 shown in FIG. 1 or each sub-control unit 32₁, 32_{N-1}, or 32_{N} shown in FIG. 2. The cell balancing circuit 110 may be provided to correspond to each of battery modules 10₁, . . . , 10_{N-1}, and 10_{N}. The cell balancing circuit 110 may control whether to discharge each battery cell (Cell 1˜Cell 12). As shown in FIG. 4, the cell balancing circuit 110 may include resistors R20 to R32 and semiconductor switches SW1 to SW12. The resistors R20 to R32 may be used to discharge a battery cell. R0˜R13 are resistors that make up the RC circuit filter included in the cell balancing circuit. A field effect transistor (FET), a bipolar junction transistor (BJT), or the like may be used as the semiconductor switch.

The communication circuit 120 may support wired communication or wireless communication between the battery management apparatus 100 and an external device (e.g., a sub-control unit, an electronic control unit (ECU), or the like). The communication circuit 120 may include a wireless communication circuit (e.g., a cellular communication circuit, a short range wireless communication circuit, or a global navigation satellite system (GNSS) communication circuit) or a wired communication circuit (e.g., a local area network (LAN) communication circuit or a power line communication circuit).

The detection circuit 130 may detect pieces of state information (e.g., voltages, currents, temperatures, and/or the like) of battery cells of each of the battery module 10₁, . . . , 10_{N-1}, or 10_{N}. The detection circuit 130 may measure a voltage, a current, a temperature, and/or the like of each battery cell using sensors, such as a voltage sensor, a current sensor, and/or a temperature sensor mounted on each of the battery cells constituting the battery module 10₁, . . . , 10_{N-1}, or 10_{N} connected to the detection circuit 130. The detection circuit 130 may store the measured pieces of sensor data in a memory) or may immediately transmit the measured pieces of sensor data to the control unit 140.

The control unit 140 may control the overall operation of the battery management apparatus 100. The control unit 140 may include a processor and a memory. The processor may be implemented as at least one of processing devices such as an application specific integrated circuit (ASIC), a digital signal processor (DSP), a programmable logic device (PLD), a field programmable gate array (FPGA), a central processing unit (CPU), a microcontroller, or a microprocessor. The memory may be a non-transitory storage medium, which stores instructions executed by the processor. The memory may be implemented as at least one of storage media (or recording media) such as a flash memory, a hard disk, a solid state disk (SSD), a secure digital (SD) card, a random access memory (RAM), a static RAM (SRAM), a read only memory (ROM), a programmable ROM (PROM), an electrically erasable and programmable ROM (EEPROM), or an erasable and programmable ROM (EPROM). The memory may store software for supporting a function of the battery management apparatus 100. The software may include a measuring algorithm for voltage, current and temperature, a state of charge (SOC) calculation algorithm, a state of health (SOH) estimation algorithm, a cell balancing algorithm, a thermal management algorithm, a diagnostic algorithm, a protection algorithm, an algorithm for communication with vehicle, and/or the like.

The control unit 140 may determine whether there is a need to perform cell balancing for each of battery modules 10₁, . . . , 10_{N-1}, and 10_{N} using the detection circuit 130 connected for each of the battery modules 10₁, . . . , 10_{N-1}, and 10_{N}. The control unit 140 may monitor voltages of the battery cells of each of the battery module 10₁, . . . , 10_{N-1}, or 10_{N} using the detection circuit 130. The control unit 140 may calculate a voltage deviation between the battery cells by means of the monitoring. The control unit 140 may determine whether to perform cell balancing based on the calculated voltage deviation between the battery cells. When the voltage deviation (e.g., a difference in an average voltage) between the battery cells is greater than a predetermined threshold as a result of the monitoring, the control unit 140 may determine to perform the cell balancing. When the voltage deviation between the battery cells is less than or equal to the predetermined threshold, the control unit 140 may determine not to perform the cell balancing.

When it is determined to perform the cell balancing, the control unit 140 may identify (or determine) a minimum cell voltage among the voltages of the battery cells. The control unit 140 may identify a battery cell (or a cell number) with the minimum cell voltage.

The control unit 140 may calculate deviations (or voltage differences) between the minimum cell voltage and the remaining cell voltages. As an example, when the voltage of a first battery cell among first to fifth battery cells is the minimum cell voltage, the control unit 140 may calculate a deviation between the first battery cell and the second battery cell, a deviation between the first battery cell and the third battery cell, a deviation between the first battery cell and the fourth battery cell, and a deviation between the first battery cell and the fifth battery cell. The first to fifth battery cells refer to 5 battery modules among the battery module 101, . . . , 10N-1, and 10N.

The control unit 140 may select a battery cell (i.e., a target cell) needing cell balancing based on the calculated deviations between the minimum cell voltage and the remaining cell voltages. In other words, the control unit 140 may determine whether there is a need to perform cell balancing (or whether there is a need to perform balancing) for each battery cell based on the calculated deviations between the minimum cell voltage and the remaining cell voltages.

The control unit 140 may calculate a balancing required time for each of target cells selected as battery cells needing the cell balancing. The balancing required time may be defined as a time necessary (or required) for cell balancing of a specific battery cell. The control unit 140 may calculate a balancing required time of the target cell based on a deviation between the minimum cell voltage and a cell voltage of the target cell. Furthermore, the control unit 140 may calculate a balancing required time of the target cell based on an SOC of the target cell. The control unit 140 may determine a balancing required time of each of the remaining battery cells, which are not selected as the target cells, as 0 seconds.

The control unit 140 may perform battery cell grouping based on whether there is the need to perform the balancing for each battery cell and/or the balancing required time for each battery cell. The control unit 140 may set at least two target cells adjacent to each other among the target cells as one group. The control unit 140 may assign group identification information (e.g., a group number or the like) for each of the set groups. The control unit 140 may classify the set groups into at least two groups. For example, the control unit 140 may classify groups into a group, a group number of which is even, (or a first group) and a group, a group number of which is odd, (or a second group).

To group the battery cells, the control unit 140 may determine whether there is a need to perform balancing for each battery cell. The control unit 140 may determine whether the balancing required time of each battery cell is greater than a predetermined time (e.g., 0 seconds). When it is determined that the balancing required time is greater than the predetermined time, the control unit 140 may determine that the battery cell needs the cell balancing. When it is determined that the balancing required time is not greater than the predetermined time, the control unit 140 may determine that the battery cell does not need the cell balancing. The control unit 140 may determine whether there is a need to perform balancing for all the battery cells.

The control unit 140 may apply a first group filter to the result of determining whether there is the need to perform the balancing for each battery cell, and thus the control unit 140 may a first group balancing switch. The control unit 140 may classify an even number group needing cell balancing among groups of at least two battery cells adjacent to each other by performing an “AND” operation on the result of determining whether there is the need to perform the balancing for each battery cell and the first group filter. The control unit 140 may set a balancing switch mapped to a battery cell, which belongs to the classified even number group to the first group balancing switch. The control unit 140 may ensure a balancing switch number, which belongs to the first group balancing switch.

The control unit 140 may apply a second group filter to the result of determining whether there is the need to perform the balancing for each battery cell, and thus the control unit 140 may set a second group balancing switch. The control unit 140 may classify an even number group needing cell balancing among the groups of the at least two battery cells adjacent to each other by performing an “AND” operation on the result of determining whether there is the need to perform the balancing for each battery cell and the second group filter. The control unit 140 may set a balancing switch mapped to a battery cell, which belongs to the classified even number group, to the second group balancing switch. The control unit 140 may ensure a balancing switch number, which belongs to the second group balancing switch.

The control unit 140 may determine whether a maximum cell voltage among the voltages of the battery cells is less than a predetermined trigger voltage. The trigger voltage may be used as a criterion for variably applying a balancing switch control strategy for cell balancing. The trigger voltage may be previously selected with regard to ratings of elements, for example, a resistor, a switch, a wire, a printed circuit board (PCB) pattern, which constitute a system.

When the maximum cell voltage is less than the predetermined trigger voltage, the control unit 140 may determine to apply group control (or a first control strategy). When the maximum cell voltage is greater than or equal to the predetermined trigger voltage, the control unit 140 may determine to apply existing individual control (or a second control strategy).

When it is determined to apply the first control strategy, the control unit 140 may perform whether first group cell balancing is performed in a previous stage (or a previous period). When it is determined that the first group cell balancing is performed in the previous stage, the control unit 140 may determine to perform second group cell balancing.

When it is determined to perform the second group cell balancing, the control unit 140 may turn on the second group balancing switch. After turning on the second group balancing switch using a timer or the like, the control unit 140 may determine whether a predetermined time elapses. When it is determined that the predetermined time elapses, the control unit 140 may turn off the second group balancing switch. When it is determined that the predetermined time does not elapse, the control unit 140 may keep the second group balancing switch turned on.

Thereafter, the control unit 140 may determine whether the state of the battery cell of the second group meets a cell balancing end condition. When the balancing required time of each of the battery cells, which belong to the second group, is 0 seconds, when the voltage of each of the battery cells, which belongs to the second group, reaches a predetermined target voltage, and/or when the SOC of each of the battery cells, which belong to the second group, reaches a predetermined target SOC, the control unit 140 may determine to end the cell balancing.

When it is determined that the first group cell balancing is not performed in the previous stage, the control unit 140 may determine to perform first group cell balancing. When it is determined to perform the first group cell balancing, the control unit 140 may turn on the first group balancing switch. After turning on the first group balancing switch using the timer or the like, the control unit 140 may determine whether the predetermined time elapses. When it is determined that the predetermined time elapses, the control unit 140 may turn off the first group balancing switch. When it is determined that the predetermined time does not elapse, the control unit 140 may keep the first group balancing switch turned on.

Thereafter, the control unit 140 may determine whether the state of the battery cell of the first group meets the cell balancing end condition. When the balancing required time of each of the battery cells, which belong to the first group, is 0 seconds, when the voltage of each of the battery cells, which belong to the first group, reaches the predetermined target voltage, and/or when the SOC of each of the battery cells, which belong to the first group, reaches the predetermined target SOC, the control unit 140 may determine to end the cell balancing.

When it is determined to apply the second control strategy, the control unit 140 may determine whether the first group cell balancing is performed in the previous stage. The first cell balancing may be defined as cell balancing for a battery cell (or a first battery cell), a cell number of which is even, among battery cells needing cell balancing. When it is determined that the first cell balancing is performed in the previous stage, the control unit 140 may determine to perform second cell balancing. The second cell balancing may be defined as cell balancing for a battery cell (or a second battery cell), a cell number of which is odd, among the battery cells needing the cell balancing. When it is determined to perform the second cell balancing, the control unit 140 may turn on a second balancing switch. For example, the controller 140 may turn on balancing switches (or the second balancing switch) corresponding to battery cells (or the second battery cell), a cell number of which corresponds to an odd number, among the battery cells needing the cell balancing. After turning on the second balancing switch, the control unit 140 may determine whether the predetermined time elapses using the timer or the like. When it is determined that the predetermined time elapses, the control unit 140 may turn off the second balancing switch. Next, the control unit 140 may determine whether the state of the second battery cell meets the cell balancing end condition. When the balancing required time of each of the second battery cells is 0 seconds, when the voltage of the second battery cell reaches the predetermined target voltage, and/or when the SOC of the second battery cell reaches the predetermined target SOC, the control unit 140 may end the cell balancing.

When it is determined that the first cell balancing is not performed in the previous stage, the control unit 140 may determine to perform first cell balancing. When it is determined to perform the first cell balancing, the control unit 140 may turn on a first balancing switch. The first balancing switch refers to one of the switches SW1 to SW12. After turning on the first balancing switch, the control unit 140 may determine whether the predetermined time elapses using the timer or the like. When it is determined that the predetermined time elapses, the control unit 140 may turn off the first balancing switch. When it is determined that the predetermined time does not elapse, the control unit 140 may keep the first balancing switch turned on. Next, the control unit 140 may determine whether the state of the first battery cell meets the cell balancing end condition. When the balancing required time of the first battery cell is 0 seconds, when the voltage of the first battery cell reaches the predetermined target voltage, and/or when the SOC of the first battery cell reaches the predetermined target SOC, the control unit 140 may end the cell balancing.

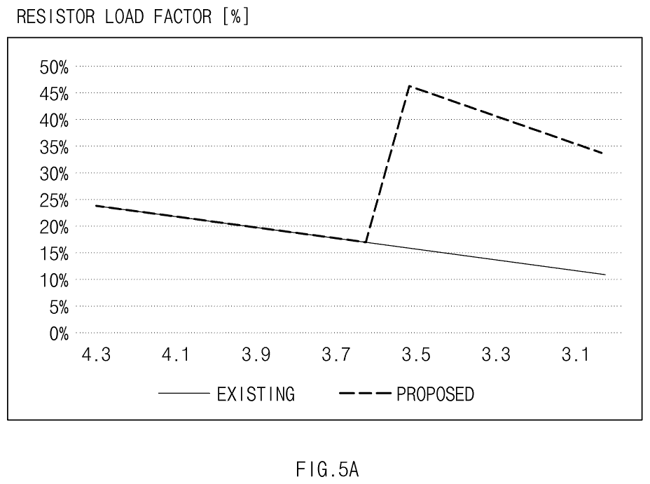

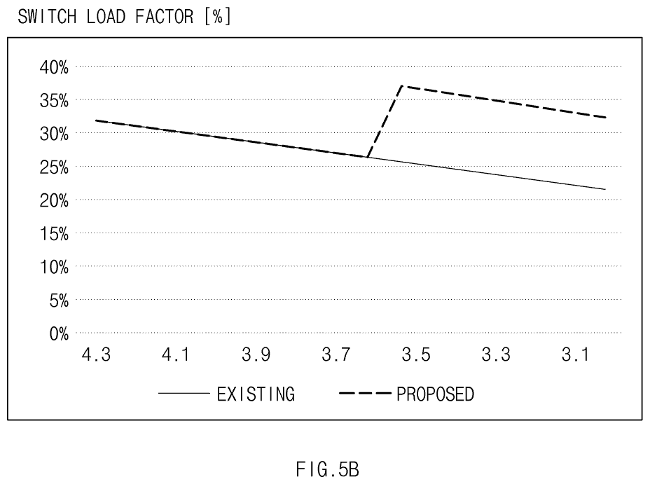

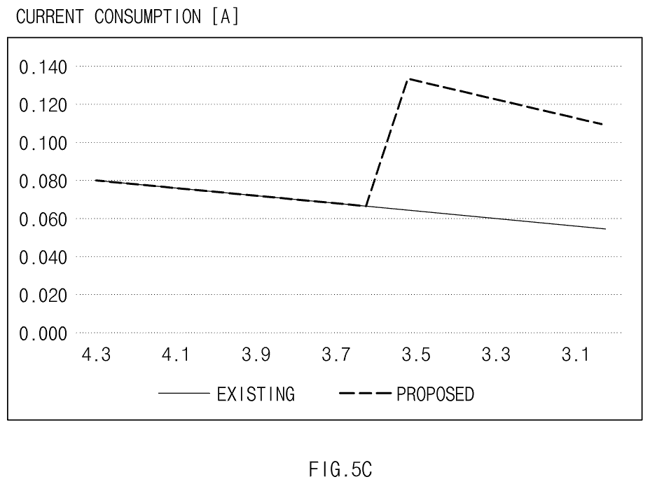

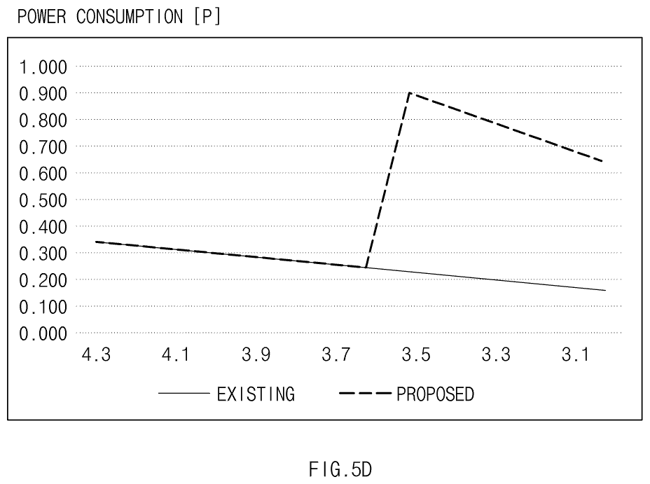

FIGS. 5A-5D are drawings for describing selection of a trigger voltage according to an embodiment of the present disclosure.

The trigger voltage may be selected with regard to a load factor of a balancing resistor and a load factor of a balancing switch. Referring to FIGS. 5A and 5B, when the resistor load factor is set to less than 50% and the switch load factor is set to less than 40%, the trigger voltage may be selected as 3.5 V.

Referring to FIG. 5C, when the group control strategy is applied (proposed) when the trigger voltage is 3.5 V, it may be identified that the balancing current increases twice compared to before. Furthermore, referring to FIG. 5D, when the group control strategy is applied when the trigger voltage is 3.5 V, it may be identified that the resistor power consumption increases about 3.6 times compared to before. In other words, when the group control strategy is applied and the battery cell decreases in voltage, the cell balancing current increases in magnitude to maintain a cell balancing speed.

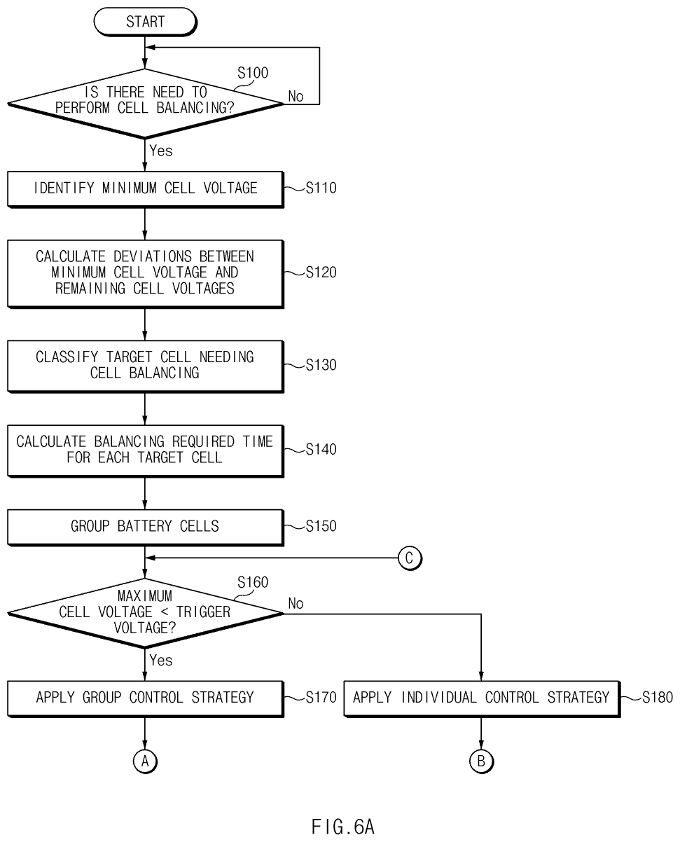

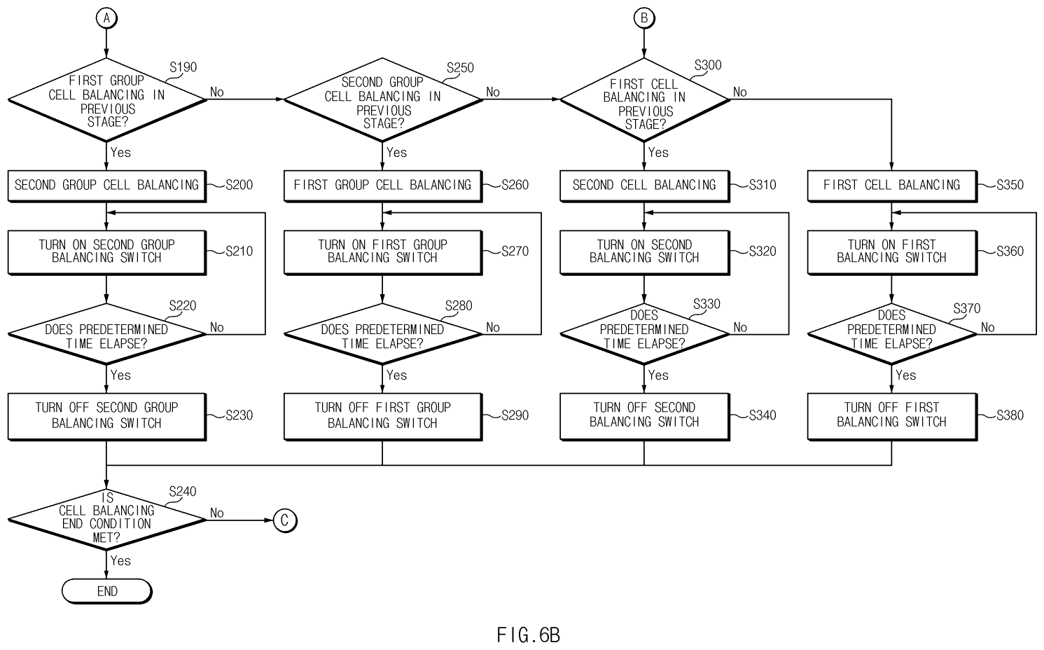

FIGS. 6A and 6B are flowcharts illustrating a cell balancing method of a battery management apparatus according to an embodiment of the present disclosure. A description is given of an example of cell balancing for one battery module to help understanding of the present disclosure in the present embodiment.

In S100, a control unit 140 of a battery management apparatus 100 may determine whether there is a need to perform cell balancing. The control unit 140 may measure voltages of battery cells of a battery module 10₁, . . . , 10_{N-1}, or 10_{N} connected with a detection circuit 130 using the detection circuit 130. The control unit 140 may calculate a deviation between the measured voltages (or cell voltages) of the battery cells. When the calculated deviation is greater than a predetermined threshold, the control unit 140 may determine that there is the need to perform the cell balancing. Meanwhile, when the calculated deviation is less than or equal to the predetermined threshold, the control unit 140 may determine that there is no need to perform the cell balancing.

When there is the need to perform the cell balancing, in S110 (Yes in S100), the control unit 140 may identify a minimum cell voltage among the voltages (or the cell voltages) of the battery cells. The control unit 140 may select the lowest cell voltage among the cell voltages measured by the detection circuit 130 as the minimum cell voltage.

In S120, the control unit 140 may calculate deviations between the minimum cell voltage and the remaining cell voltages. For example, when there are first to fifth battery cells and the voltage of the first battery cell is minimum, the control unit 140 may calculate a voltage difference between the first battery cell and the second battery cell, a voltage difference between the first battery cell and the third battery cell, a voltage difference between the first battery cell and the fourth battery cell, and a voltage difference between the first battery cell and the fifth battery cell, when the voltage of the first battery cell is the minimum cell voltage.

In S130, the control unit 140 may classify a target cell needing cell balancing (or balancing) among the battery cells based on the deviations between the minimum cell voltage and the remaining cell voltages. The control unit 140 may determine whether there is a need to perform cell balancing for each battery cell based on the deviations between the minimum cell voltage and the remaining cell voltages. The control unit 140 may determine that there is the need to perform the cell balancing for a battery cell, which has a difference with the minimum cell voltage by a predetermined reference voltage or more. The control unit 140 may determine that there is no need to perform the cell balancing for a battery cell, which does not have the difference with the minimum cell voltage by the predetermined reference voltage or more.

In S140, the control unit 140 may calculate a balancing required time for each target cell. The control unit 140 may calculate a balancing required time for each of battery cells needing the cell balancing. The balancing required time may be defined as a time necessary for cell balancing of a specific battery cell.

In S150, the control unit 140 may group battery cells based on whether there is the need to perform the balancing for each battery cell and the balancing required time for each battery cell. The control unit 140 may classify the battery cells into a first group (or an even group) and a second group (or an odd group).

In S160, the control unit 140 may determine whether a maximum cell voltage is less than a predetermined trigger voltage. The trigger voltage may be previously selected with regard to ratings of elements, for example, a resistor, a switch, a wire, a PCB pattern, which constitute a system.

When it is determined the maximum cell voltage is less than the predetermined trigger voltage (Yes in S160), in S170, the control unit 140 may determine to apply a group control strategy (or a first control strategy).

When it is determined that the maximum cell voltage is not less than the predetermined trigger voltage (No in S160), in S180, the control unit 140 may determine to apply an individual control strategy (or a second control strategy).

When it is determined to apply the group control strategy in S170, in S190, the control unit 140 may determine whether first group cell balancing is performed in a previous stage (or a previous period). The first group cell balancing may refer to cell balancing for at least one cell group, which belongs to the first group. Each of the at least one cell group may be composed of at least two battery cells, which are adjacent to each other. The first group may include cell groups, each of which has an even identification number (or an even group number) assigned to the cell group.

When it is determined that the first group cell balancing is performed (Yes in S190), in S200, the control unit 140 may determine second group cell balancing. The second group cell balancing may refer to cell balancing for at least one cell group, which belongs to the second group. Each cell group may comprise at least two battery cells, which are adjacent to each other. The second group may include cell groups, each of which has an odd identification number assigned to the cell group.

In S210, the control unit 140 may turn on a second group balancing switch. The second group balancing switch may include balancing switches corresponding to battery cells which belong to the second group.

After turning on the second group balancing switch, in S220, the control unit 140 may determine whether a predetermined time elapses.

When it is determined that the predetermined time elapses (Yes in S220), in S230, the control unit 140 may turn off the second group balancing switch. When it is determined that the predetermined time does not elapse (No in S220), in S210, the control unit 140 may keep the second group balancing switch turned on.

After turning off the second group balancing switch, in S240, the control unit 140 may determine whether a cell balancing end condition is met. When a total balancing required time necessary for the second group cell balancing is a predetermined time (e.g., 0 seconds) (i.e., when the balancing required time of all the battery cells, which belong to the second group, is 0 seconds), when a cell voltage of the battery cells, which belong to the second group, reaches a predetermined target voltage, or when an SOC of the battery cells, which belong to the second group (Yes in S240), reaches a predetermined target SOC, the control unit 140 may determine to end the cell balancing.

When it is determined that the first group cell balancing is not performed in the previous stage (No in S190), in S250, the control unit 140 may determine whether second group cell balancing is performed in the previous stage.

When it is determined that the second group cell balancing is performed in the previous stage (Yes in S250), in S260, the control unit 140 may determine first group cell balancing.

In S270, the control unit 140 may turn on a first group balancing switch. The first group balancing switch may include balancing switches corresponding to the battery cells, which belong to the first group.

After turning on the first group balancing switch, in S280, the control unit 140 may determine whether the predetermined time elapses. The control unit 140 may measure a time, which elapses after turning on the first group balancing switch, using a timer provided inside or outside the control unit 140.

When it is determined that the predetermined time elapses (Yes in S280), in S290, the control unit 140 may turn off the first group balancing switch. After turning off the first group balancing switch, the control unit 140 may perform S240. In S240, when a total balancing required time necessary for the first group cell balancing is the predetermined time (e.g., 0 seconds) (i.e., when the balancing required time of all the battery cells which belong to the first group is 0 seconds), when the cell voltage of the battery cells, which belong to the first group, reaches the predetermined target voltage, or when an SOC of the battery cells, which belong to the first group, reaches the predetermined target SOC (Yes in S240), the control unit 140 may determine to end the cell balancing. The control unit 140 may end cell balancing of a cell group meeting the cell balancing end condition. When it is determined that the predetermined time does not elapse (No in S280), in S270, the control unit 140 may keep the first group balancing switch turned on.

When it is determined to apply the individual control strategy in S180 or when it is determined that the second group cell balancing is not performed in the previous stage (No in S250), in S300, the control unit 140 may determine whether first cell balancing is performed in the previous stage. The first cell balancing may be defined as cell balancing for battery cells to which even numbers are assigned as cell numbers.

When it is determined that the first cell balancing is performed in the previous stage (Yes in S300), in S310, the control unit 140 may determine second cell balancing. The second cell balancing may be defined as cell balancing for battery cells to which odd numbers are assigned as cell numbers.

In S320, the control unit 140 may turn on a second balancing switch. The second balancing switch may be defined as a balancing switch corresponding to each of the battery cells to which the even numbers are assigned as the cell numbers.

After turning on the second balancing switch, in S330, the control unit 140 may determine whether the predetermined time elapses. The control unit 140 may turn on the second balancing switch during the predetermined time.

When it is determined that the predetermined time elapses (Yes in S330), in S340, the control unit 140 may turn off the second balancing switch. Thereafter, the control unit 140 may perform S240. In S240, when a balancing required time of the battery cell to which the even number is assigned as the cell number is the predetermined time (e.g., 0 seconds), when the voltage of the battery cell to which the even number is assigned as the cell number reaches the predetermined target voltage, or when an SOC of the battery cell to which the even number is assigned as the cell number reaches the predetermined target SOC (Yes in S240), the control unit 140 may end the cell balancing of the battery cell. When it is determined that the predetermined time does not elapse (No in S330), in S320, the control unit 140 may keep the second balancing switch turned on.

When it is determined that the first cell balancing is not performed in the previous stage (No in S300), in S350, the control unit 140 may determine first cell balancing.

In S360, the control unit 140 may turn on a first balancing switch. The first balancing switch may be defined as a balancing switch corresponding to each of battery cells to which odd numbers are assigned as cell numbers.

After turning on the first balancing switch, in S370, the control unit 140 may determine whether the predetermined time elapses. The control unit 140 may turn on the first balancing switch during the predetermined time.

When it is determined that the predetermined time elapses (Yes in S370), in S380, the control unit 140 may turn off the first balancing switch. Thereafter, the control unit 140 may perform S240. In S240, when a balancing required time of the battery cell to which the odd number is assigned as the cell number is the predetermined time (e.g., 0 seconds), when the voltage of the battery cell to which the odd number is assigned as the cell number reaches the predetermined target voltage, or when an SOC of the battery cell to which the odd number is assigned as the cell number reaches the predetermined target SOC (Yes in S240), the control unit 140 may end the cell balancing of the battery cell. When it is determined that the predetermined time does not elapse (No in S370), in S360, the control unit 140 may keep the first balancing switch turned on.

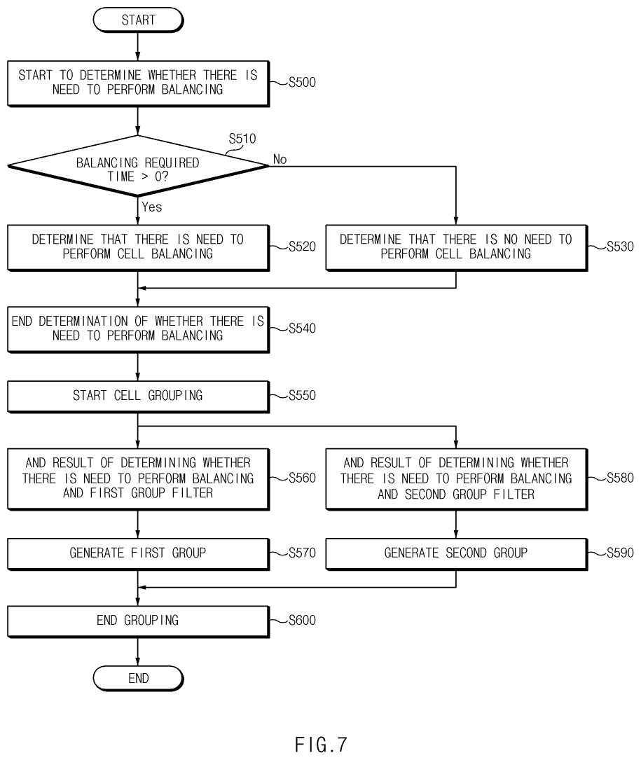

FIG. 7 is a flowchart illustrating a battery cell grouping process according to an embodiment of the present disclosure.

In S500, a control unit 140 may start to determine whether there is a need to perform balancing for each battery cell.

In S510, the control unit 140 may determine whether a balancing required time is greater than a predetermined time (e.g., 0 seconds) for each battery cell. The control unit 140 may calculate the balancing required time for each battery cell based on a predetermined reference SOC. The reference SOC may be defined as an SOC, which is a criterion for determining whether there is a need to perform cell balancing of a battery cell.

When it is determined that the balancing required time is greater than the predetermined time (Yes in S510), in S520, the control unit 140 may determine that there is a need to perform cell balancing for the battery cell.

When it is determined that the balancing required time is not greater than the predetermined time (No in S510), in S530, the control unit 140 may determine that there is no need to perform the cell balancing for the battery cell.

When the determination of whether there is the need to perform the cell balancing for each battery cell is completed, in S540, the control unit 140 may end the determination of whether there is the need to perform the balancing. The control unit may binarize the results of determining whether there is the need to perform the balancing, which correspond to cell numbers of battery cells, to generate a table.

When the determination of whether there is the need to perform the balancing is ended, in S550, the control unit 140 may start cell grouping.

In S560, the control unit 140 may perform an “AND” operation on the result of determining whether there is the need to perform the balancing for each battery cell and a first group filter. The control unit 140 may apply the first group filter to the result of determining whether there is the need to perform the balancing for each battery cell.

In S570, the control unit 140 may generate a first group based on the result of the “AND” operation in S560. The control unit 140 may apply the first group filter to the result of determining whether there is the need to perform the balancing for each battery cell. Thus, the control unit 140 may classify a cell group having an even group identification number. The cell group needs cell balancing among cell groups comprising two or more battery cells adjacent to each other.

In S580, the control unit 140 may perform an “AND” operation on the result of determining whether there is the need to perform the balancing for each battery cell and a second group filter. The control unit 140 may apply the second group filter to the result of determining whether there is the need to perform the balancing for each battery cell.

In S590, the control unit 140 may generate a second group based on the result of the “AND” operation in S580. The control unit 140 may apply the second group filter to the result of determining whether there is the need to perform the balancing for each battery cell. Thus, the control unit 140 may classify a cell group having an odd group identification number. The cell group needs cell balancing among the cell groups comprising the two or more battery cells adjacent to each other.

When the classification of cell groups, which belong to the first group and the second group, is completed, in S600, the control unit 140 may end the grouping.

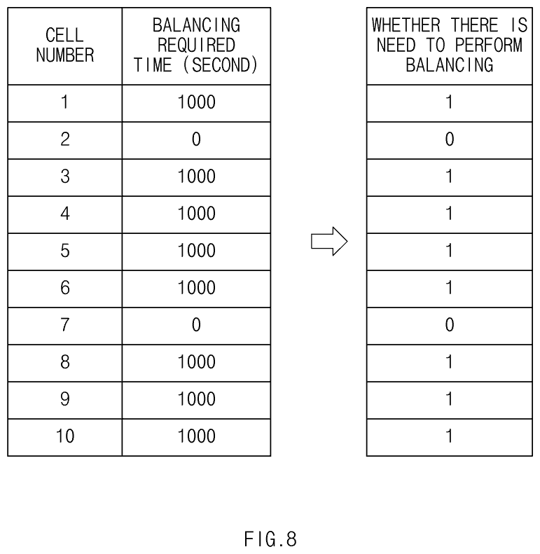

FIG. 8 is a drawing for describing a method for determining whether there is a need to perform balancing for each battery cell according to an embodiment of the present disclosure.

Referring to FIG. 8, a control unit 140 may calculate a balancing required time for each battery cell based on a predetermined SOC. The predetermined SOC may be defined as a reference SOC for determining whether there is a need to perform cell balancing of a battery cell. The control unit 140 may set a balancing required time calculated for each cell number. The cell number may be used as identification information for identifying a battery cell.

The control unit 140 may determine whether a balancing required time mapped to a cell number is greater than 0 seconds. When the balancing required time is greater than 0 seconds, the control unit 140 may determine that there is need to perform the cell balancing for the battery cell with the cell number. The control unit 140 may set the result of determining whether there is the need to perform the balancing of the battery cell mapped to the cell number to “1”.

When the balancing required time is 0 seconds, the control unit 140 may determine that there is no need to perform the cell balancing for the battery cell with the cell number. The control unit 140 may set the result of determining whether there is the need to perform the balancing of the battery cell mapped to the cell number to “0”.

The control unit 140 may generate the result of determining whether there is the need to perform the balancing for each battery cell as a table in a binary format composed of “1” and “0”.

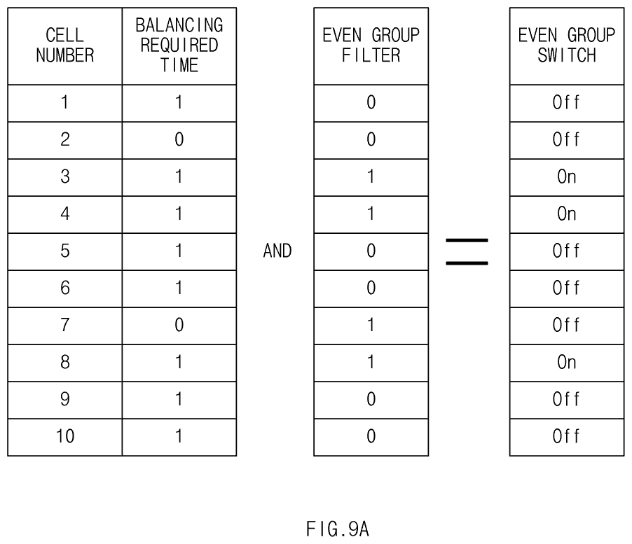

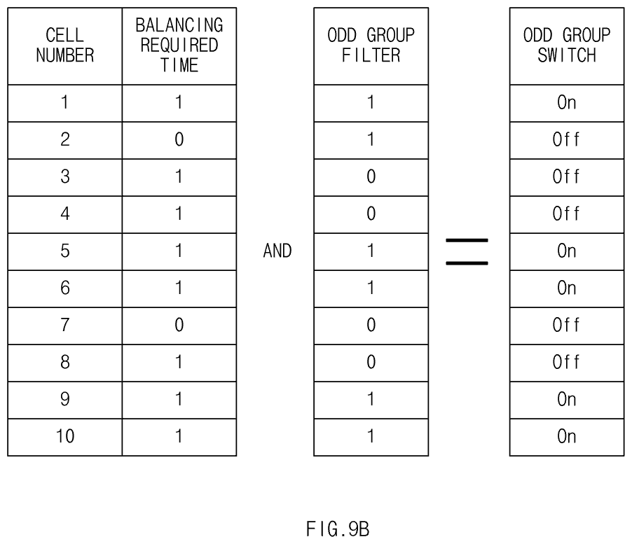

FIGS. 9A and 9B are drawings for describing cell grouping according to an embodiment of the present disclosure.

Referring to FIG. 9A, a control unit 140 may perform an “AND” operation on a binarized table in which the result of determining whether there is a need to perform balancing for each battery cell and an even group filter. The control unit 140 may determine battery cells in which the result of the “AND” operation is “1” among battery cells, for example, balancing switches corresponding to cell numbers 3, 4, and 8 as even group switches.

Referring to FIG. 9B, the control unit 140 may perform an “AND” operation on a binarized table in which the result of determining whether there is a need to perform balancing for each battery cell and an odd group filter. The control unit 140 may determine battery cells in which the result of the “AND” operation is “1” among battery cells, for example, balancing switches corresponding to cell numbers 1, 5, 6, 9, and 10 as odd group switches.

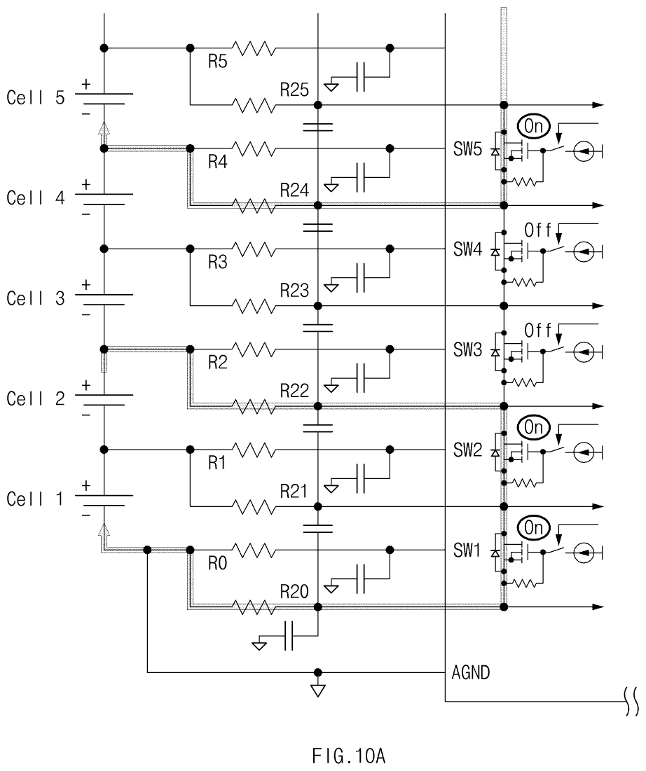

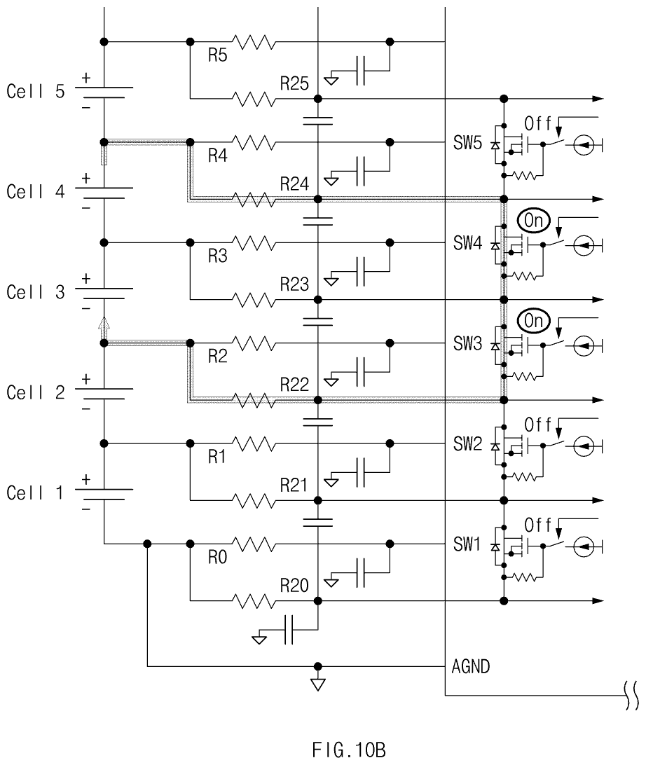

FIGS. 10A and 10B are drawings for describing group control according to an embodiment of the present disclosure.

A control unit 140 of a battery management apparatus 100 may group adjacent (or neighboring) cells among cell balancing target cells and may simultaneously turn on and off a plurality of balancing switches. The control unit 140 may apply an existing switch control strategy (or a second control strategy) when the cell voltage is higher than a predetermined voltage. The control unit 140 may apply a group switch control strategy (or a first control strategy) when the cell voltage is lower than the predetermined voltage. Thus, a balancing switch may be controlled.

As shown in FIGS. 10A and 10B, when Cell 1, Cell 2, and Cell 5 are an odd group and Cell 3 and Cell 4 are an even group, the control unit 140 may simultaneously turn on balancing switches SW1, SW2, and SW3 mapped to battery cells, which belong to the odd group, and may turn off balancing switches SW3 and SW4 mapped to battery cells, which belong to the even group. Thereafter, when a predetermined time elapses, the control unit 140 may turn off the balancing switches SW1, SW2, and SW5 and may turn on the balancing switches SW3 and SW4. Whenever the predetermined time elapses, the control unit 140 may alternately turn on and off the balancing switches SW1, SW2, and SW5 in the odd group and the balancing switches SW3 and SW4 in the even group. Thus, although the cell voltage decreases to a predetermined voltages or less when applying a group switch control strategy, because it is able to perform cell balancing using a large balancing current in preparation for when applying an existing switch control strategy, a problem in which a balancing current decreases may be overcome as the cell voltage decreases when applying the existing switch control strategy.

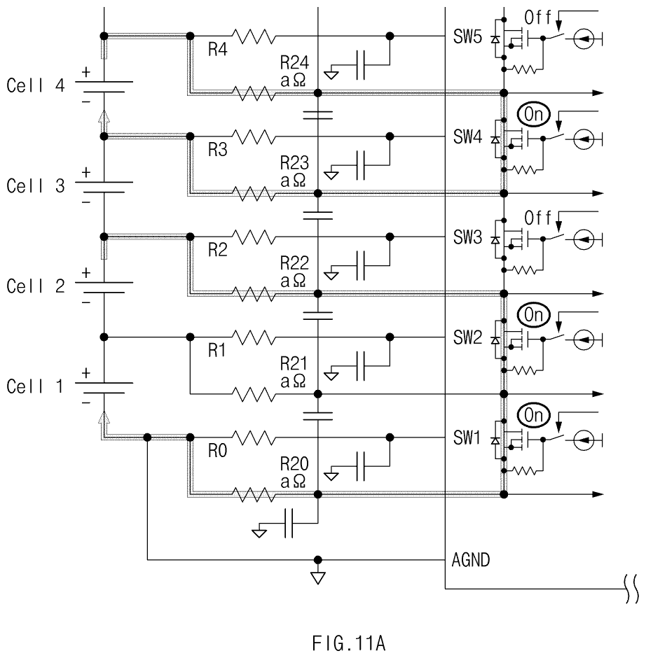

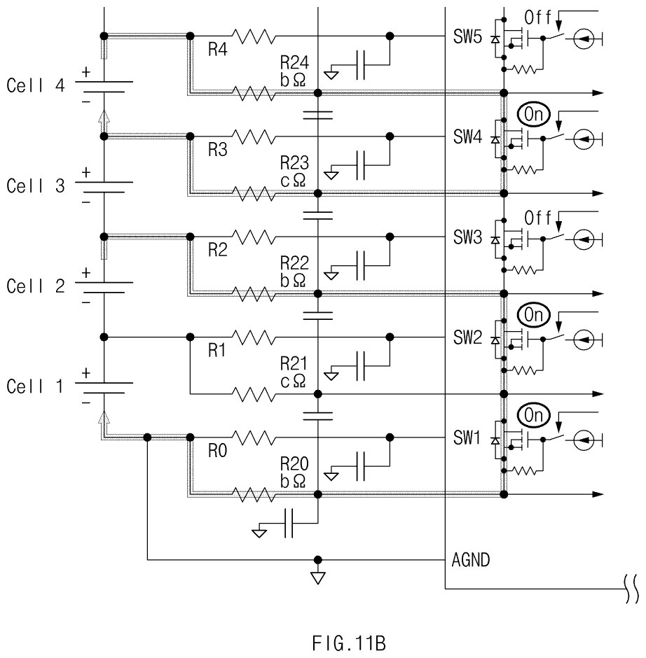

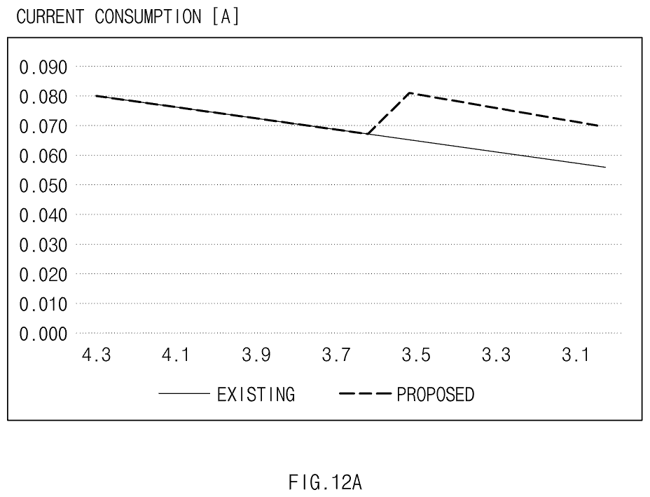

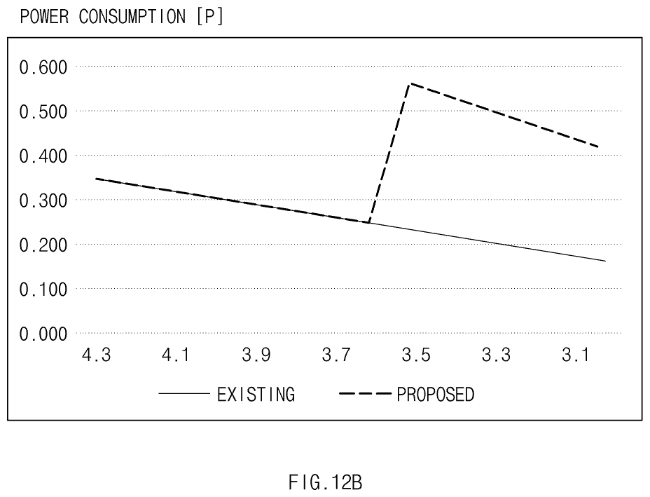

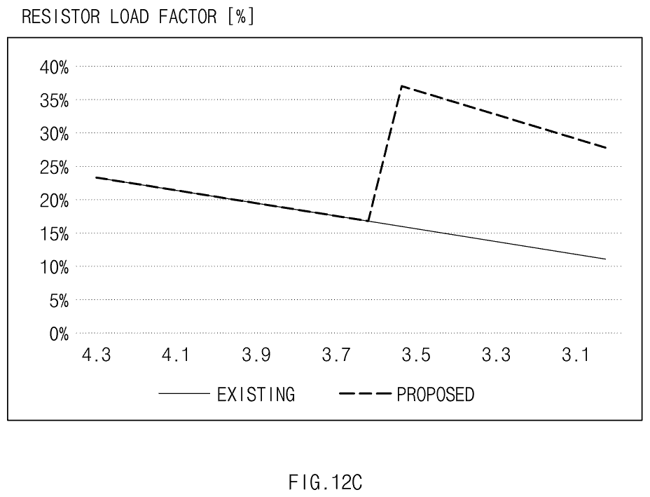

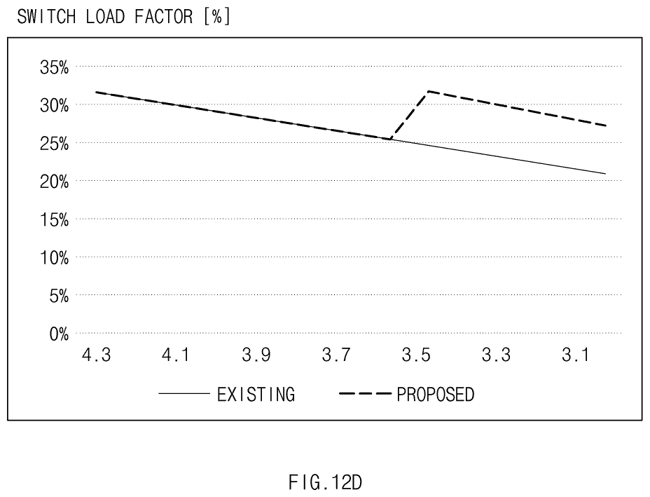

FIGS. 11A and 11B are drawings for describing a cell balancing circuit according to another embodiment of the present disclosure. FIGS. 12A-12D illustrate performance comparison graphs according to a ratio of balancing resistors according to another embodiment of the present disclosure.

Referring to FIG. 11A, sizes aΩ and aΩ of balancing resistors R20 and R21 applied to an existing cell balancing circuit are selected at a symmetry ratio (e.g., R20:R21=1:1).

Referring to FIG. 11B, the sizes of the balancing resistors R20 and R21 applied to a cell balancing circuit 110 proposed according to an embodiment of the present disclosure may be applied at an asymmetry ratio. For example, the sizes bΩ and cΩ of the resistors R20 and R21 may be selected at 4:1.

Referring to FIG. 12A, unlike when the resistor size at a symmetry ratio is applied, when the resistor size at an asymmetry ratio is applied, a balancing current may increase in magnitude although a cell voltage decreases.

Referring to FIG. 12B, compared to an existing technology which applies the resistor size at the symmetry ratio, when applying the resistor size at the asymmetry ratio, because power consumption of a resistor increases, a time taken to perform cell balancing may decrease.

Referring to FIGS. 12C and 12D, it may be identified that it is able to prevent damage to a balancing switch and a balancing resistor, as the magnitude of a balancing current and power consumption of a balancing resistor increase, but the resistor load factor is less than 40% and the switch load factor is less than 35%.

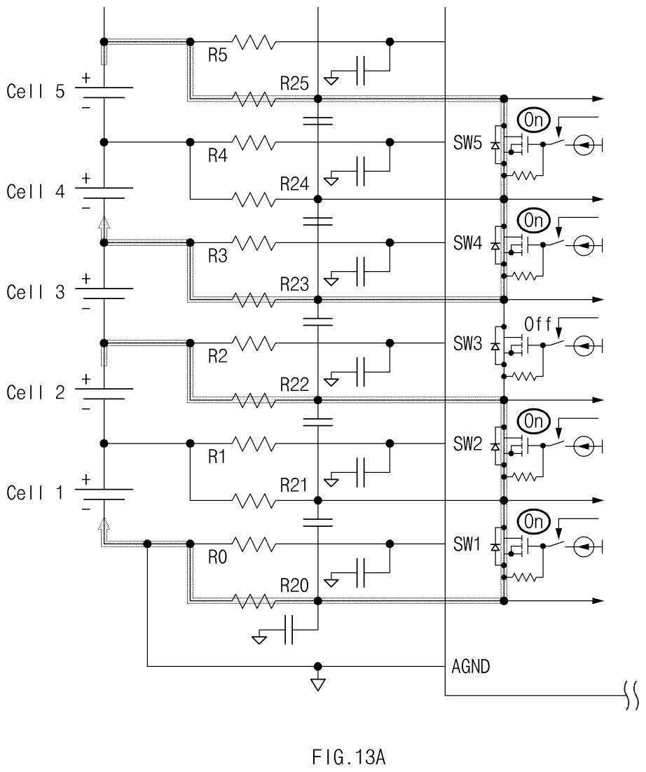

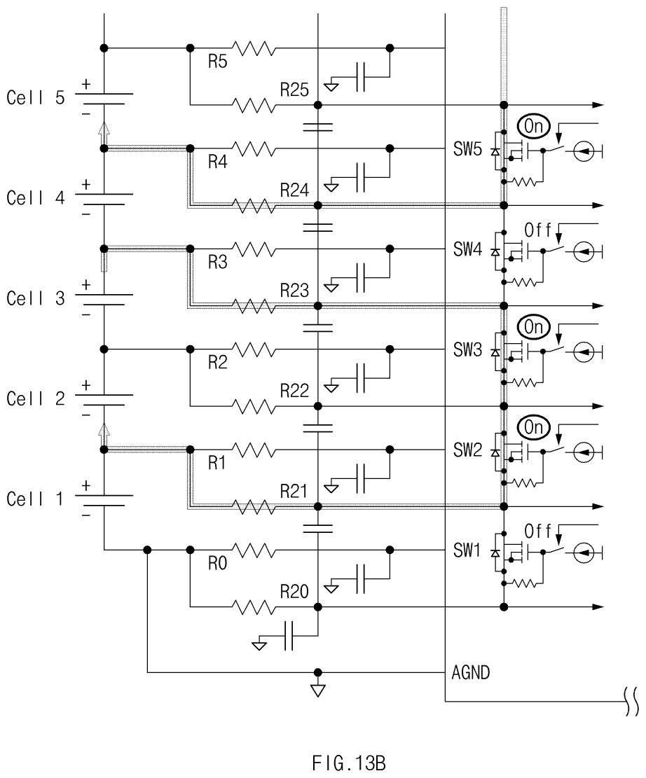

FIGS. 13A and 13B are drawings for describing cell balancing switch control according to another embodiment of the present disclosure.

Referring to FIGS. 13A and 13B, a control unit 140 may turn on balancing switches SW1 and SW2 to discharge battery cells Cell 1 and Cell 2. When a predetermined time elapses after turning on the balancing switches SW1 and SW2, the control unit 140 may turn off the balancing switches SW1 and SW2 and may turn on balancing switches SW2 and SW3. Thus, battery cells Cell 2 and Cell 3 may be discharged. When the predetermined time elapses after turning on the balancing switches SW2 and SW3, the control unit 140 may turn off the balancing switches SW2 and SW3 and may turn on the balancing switches SW1 and SW2. As such, the control unit 140 may alternately turn on the balancing switches SW1 and SW2 and the balancing switches SW2 and SW3.

Compared to when applying (B) a control strategy for alternately turning on the balancing switches SW1 and SW2 and balancing switches SW3 and SW4, when applying (A) a group control strategy for alternately turning on the balancing switches SW1 and SW2 and the balancing switches SW2 and SW3, the control unit 140 may reduce the number of times of switching, i.e., the number of times of turning on and off. Thus, the life of a balancing switch may be increased according to a decrease in semiconductor switching loss and a decrease in switching stress.

TABLE 1

| | SW1 | SW2 | SW3 |
|---|---|---|---|
| A | 3 times per minute | Once per control | 3 times per minute |
| | | period | |
| B | 3 times per minute | 3 times per minute | 3 times per minute |

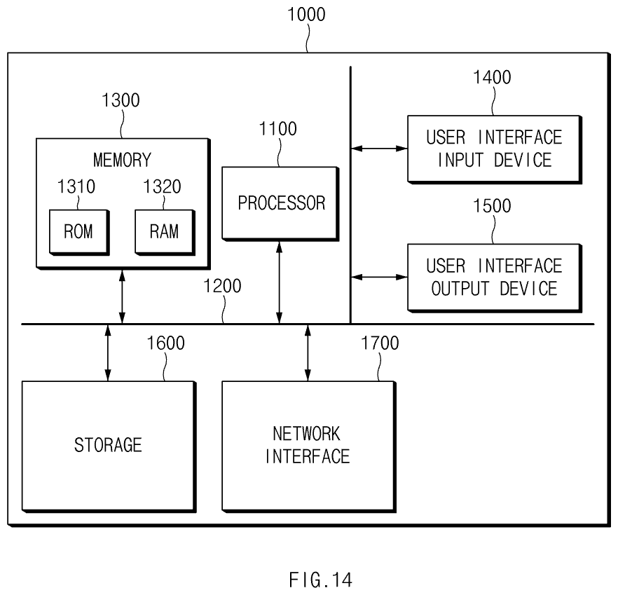

FIG. 14 is a block diagram illustrating a computing system associated with a battery management apparatus and a cell balancing method thereof according to an embodiment of the present disclosure. Referring to FIG. 14, a computing system 1000 may include at least one processor 1100, a memory 1300, a user interface input device 1400, a user interface output device 1500, storage 1600, and a network interface 1700, which are connected to each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with the embodiments disclosed in the present disclosure may be directly implemented with a hardware module, a software module, or a combination of the hardware module and the software module, which is executed by the processor 1100. The software module may reside on a storage medium (i.e., the memory 1300 and/or the storage 1600), such as a RAM, a flash memory, a ROM, an EPROM, an EEPROM, a register, a hard disc, a removable disk, and a CD-ROM. The storage medium may be coupled to the processor 1100. The processor 1100 may read out information from the storage medium and may write information in the storage medium. Alternatively, the storage medium may be integrated with the processor 1100. The processor 110 and the storage medium may reside in an application specific integrated circuit (ASIC). The ASIC may reside within a user terminal. In another case, the processor 1100 and the storage medium may reside in the user terminal as separate components.

Embodiments of the present disclosure may perform cell balancing using a cell balancing current greater than before even in a condition with a low cell voltage. Thus, a cell balancing speed may be prevented from being slow.

Furthermore, embodiments of the present disclosure may prevent acceleration of non-uniform deterioration for each cell, which is capable of occurring when repeating charging and discharging in a cell voltage imbalance state.

Furthermore, embodiments of the present disclosure may implement a cell balancing switch control strategy by changing software without changing a design of hardware.

Hereinabove, although the present disclosure has been described with reference to embodiments and the accompanying drawings, the present disclosure is not limited thereto. The present disclosure may be variously modified and altered by those having ordinary skill in the art to which the present disclosure pertains without departing from the spirit and scope of the present disclosure claimed in the following claims. Therefore, embodiments of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A battery management apparatus, comprising:
a detection circuit configured to detect pieces of state information of battery cells;
a cell balancing circuit configured to control whether to discharge each of the battery cells; and
a control unit connected to the detection circuit and the cell balancing circuit,
wherein the control unit is configured to
determine whether there is a need to perform cell balancing based on the pieces of state information of the battery cells,
group the battery cells into at least two groups, when it is determined that there is the need to perform the cell balancing,
determine whether to apply a group control strategy based on the pieces of state information of the battery cells, and
simultaneously control balancing switches in the cell balancing circuit, the balancing switches being mapped to the grouped battery cells, to perform the cell balancing, when it is determined to apply the group control strategy.

2. The battery management apparatus of claim 1, wherein the control unit is configured to:
group at least two battery cells adjacent to each other among the battery cells.

3. The battery management apparatus of claim 1, wherein the control unit is configured to:
determine whether there is a need to perform balancing for each battery cell based on a balancing required time for each battery cell;
generate a first group based on a result of determining whether there is the need to perform the balancing for each battery cell and a first group filter; and
generate a second group based on a result of determining whether there is the need to perform the balancing for each battery cell and a second group filter.

4. The battery management apparatus of claim 1, wherein the control unit is configured to:
determine whether cell balancing of battery cells of a first group among the at least two groups is performed in a previous period;
determine cell balancing of battery cells of a second group among the at least two groups, when it is determined that the cell balancing of the battery cells of the first group is performed;
turn on second group balancing switches mapped to the battery cells of the second group;
determine whether a predetermined time elapses after turning on the second group balancing switches; and
turn off the second group balancing switches, when it is determined that the predetermined time elapses.

5. The battery management apparatus of claim 1, wherein the control unit is configured to:
determine whether cell balancing of battery cells of a first group among the at least two groups is performed in a previous period;
determine the cell balancing of the battery cells of the first group, when it is determined that the cell balancing of the battery cells of the first group is not performed;
turn on first group balancing switches mapped to the battery cells of the first group;
determine whether a predetermined time elapses after turning on the first group balancing switches; and
turn off the first group balancing switches, when it is determined that the predetermined time elapses.

6. The battery management apparatus of claim 1, wherein the control unit is configured to:
determine whether a maximum cell voltage is less than a predetermined trigger voltage; and
determine to apply the group control strategy, when it is determined that the maximum cell voltage is less than the predetermined trigger voltage.

7. The battery management apparatus of claim 6, wherein the predetermined trigger voltage is previously selected with regard to ratings of elements constituting a system.

8. The battery management apparatus of claim 1, wherein the control unit is configured to:
determine whether to end cell balancing of the grouped battery cells based on a balancing required time of the battery cells.

9. The battery management apparatus of claim 1, wherein the control unit is configured to:
determine whether to end cell balancing of the grouped battery cells based on whether a voltage of the battery cells reaches a predetermined target voltage.

10. The battery management apparatus of claim 1, wherein the control unit is configured to:
determine whether to end cell balancing of the grouped battery cells based on whether a state of charge (SOC) of the battery cells reaches a predetermined target SOC.

11. A cell balancing method of a battery management apparatus, the cell balancing method comprising:
determining whether there is a need to perform cell balancing based on pieces of state information of battery cells, the pieces of state information being detected by a detection circuit;
grouping the battery cells into at least two groups, when it is determined that there is the need to perform the cell balancing;
determining whether to apply a group control strategy based on the pieces of state information of the battery cells; and
simultaneously controlling balancing switches in a cell balancing circuit, the balancing switches being mapped to the grouped battery cells, to perform the cell balancing, when it is determined to apply the group control strategy.

12. The cell balancing method of claim 11, wherein grouping the battery cells into at least two groups includes:
grouping at least two battery cells adjacent to each other among the battery cells.

13. The cell balancing method of claim 11, wherein grouping the battery cells into at least two groups includes:
determining whether there is a need to perform balancing for each battery cell based on a balancing required time for each battery cell;
generating a first group based on a result of determining whether there is the need to perform the balancing for each battery cell and a first group filter; and
generating a second group based on a result of determining whether there is the need to perform the balancing for each battery cell and a second group filter.

14. The cell balancing method of claim 11, wherein performing the cell balancing includes:
determining whether cell balancing of battery cells of a first group among the at least two groups is performed in a previous period;
determining cell balancing of battery cells of a second group among the at least two groups, when it is determined that the cell balancing of the battery cells of the first group is performed;
turning on second group balancing switches mapped to the battery cells of the second group;
determining a predetermined time elapses after turning on the second group balancing switches; and
turning off the second group balancing switches, when it is determined that the predetermined time elapses.

15. The cell balancing method of claim 11, wherein performing the cell balancing includes:
determining whether cell balancing of battery cells of a first group among the at least two groups is performed in a previous period;
determining the cell balancing of the battery cells of the first group, when it is determined that the cell balancing of the battery cells of the first group is not performed;
turning on first group balancing switches mapped to the battery cells of the first group;
determining a predetermined time elapses after turning on the first group balancing switches; and
turning off the first group balancing switches, when it is determined that the predetermined time elapses.

16. The cell balancing method of claim 11, wherein determining whether to apply the group control strategy includes:
determining whether a maximum cell voltage is less than a predetermined trigger voltage; and
determining to apply the group control strategy, when it is determined that the maximum cell voltage is less than the predetermined trigger voltage.

17. The cell balancing method of claim 16, wherein the predetermined trigger voltage is previously selected with regard to ratings of elements constituting a system.

18. The cell balancing method of claim 11, further comprising:
determining whether to end cell balancing of the grouped battery cells based on a balancing required time of the battery cells.

19. The cell balancing method of claim 11, further comprising:
determining whether to end cell balancing of the grouped battery cells based on whether a voltage of the battery cells reaches a predetermined target voltage.

20. The cell balancing method of claim 11, further comprising:
determining whether to end cell balancing of the grouped battery cells based on whether an SOC of the battery cells reaches a predetermined target SOC.
